(19) United States
(12) Patent Application Publication
(10) Pub. No.: US 2008/0293228 A1
(43) Pub. Date: Nov. 27, 2008

(54) CMOS Compatible Method of Forming Source/Drain Contacts for Self-Aligned Nanotube Devices

(76) Inventor: Amol M. Kalburge, Irvine, CA (US)

Correspondence Address: GREENBERG TRAURIG LLP (LA), 2450 COLORADO AVENUE, SUITE 400E, INTELLECTUAL PROPERTY DEPARTMENT, SANTA MONICA, CA, 90404, US

(21) Appl. No.: 12/124,827

(22) Filed: May 21, 2008

Related U.S. Application Data
(60) Provisional application No. 60/940,332, filed on May 25, 2007.

(51) Int. Cl. H01L 21/28

(52) U.S. Cl. 438/586; 257/E21.177

(57) ABSTRACT

A method is provided for forming metal contacts to nanotube devices in a standard CMOS process flow. In accordance with one feature, a method for forming source/drain contacts to nanotube devices acting as FETs is provided while minimizing metal contamination to the complementary metal oxide semiconductor (CMOS) circuitry in a standard CMOS process flow. The method includes forming nanotube devices on a semiconductor substrate during a front end process of a CMOS process flow, while forming metallic contacts for the nanotube devices during a back end process of the CMOS process flow. This enables the formation of nanotube devices to be integrated within a standard CMOS process flow, thereby opening avenues to commercializing new generation of RFCMOS technology where superior RF/analog circuitry based on nanotube devices can be combined with digital circuitry based on standard silicon CMOS.

### RELATED APPLICATIONS

This application claims the benefit of and priority to U.S. Provisional Application Ser. No. 60/940,332, filed May 25, 2007, the contents of which are incorporated by reference herein in its entirety.

### TECHNICAL FIELD

This disclosure relates generally to the field of nanotube coated wafers and, more particularly, to a method of forming source/drain contacts to nanotube devices formed on a semiconductor wafer that is compatible with a complementary metal oxide semiconductor (CMOS) process flow.

### BACKGROUND

One of the challenges facing broad commercialization of nanotube technology is the lack of a clear path for integrating carbon nanotubes (CNTs) with standard CMOS devices. CNT devices require ohmic contacts to be formed at the sources and drains of the CNT devices for the CNT devices to function as field-effect transistors (FETs), where Palladium (Pd) metal is the most commonly used source/drain ohmic contact material to the CNT devices. A commonly used technique to deposit Pd as the ohmic contact material in CNT devices is by a “lift-off” of the Pd metal using photolithography to form Pd “islands.” This lift-off photolithography technique is used only to build discrete nanotube devices (i.e., those standalone devices that are not integrated with CMOS), where such Pd “islands” can be formed underneath nanotubes or on top of nanotubes.

However, Pd is not a commonly used material in CMOS fabrication processes, because Pd can degrade CMOS device performance/reliability. Pd deposited via the above-mentioned lift-off photolithography technique is not compatible with standard CMOS fabrication processes due to high defectivity and large metal contamination of the wet benches required to lift-off the photoresist material. Further, depositing Pd using such a lift-off method to form nanotube contacts requires the Pd deposition to be done before or immediately after nanotube deposition. When attempting to integrate nanotube formation in CMOS front end processing, such a Pd deposition technique poses a danger of cross-contaminating the CMOS circuitry formed on the same wafer during front end processing as well as the fabrication equipment dedicated to front-end processing. In a standard CMOS manufacturing process, metal contamination must be avoided in all front end equipment to minimize cross-contamination and degrading of gate oxide reliability due to trace metal impurities. Thus, prior known lift-off approaches of depositing Pd as ohmic contacts to nanotube devices are not usable or compatible with standard CMOS semiconductor fabrication processes.

### SUMMARY

According to a feature of the disclosure, a method is provided integrating nanotube devices in a standard CMOS fabrication process flow without risk of cross-contamination of the CMOS components.

In one or more embodiments, a method is provided for forming metal contacts to nanotube devices in a standard CMOS process flow.

In one or more embodiments, a method is provided for forming source/drain contacts to nanotube devices, such as CNTs or the like, while minimizing the possibility of metal contamination to the complementary metal oxide semiconductor (CMOS) circuitry in a standard CMOS process flow. This enables nanotube devices to be integrated into a standard CMOS process flow, thereby opening avenues to commercializing new generations of radio frequency (RF) CMOS technology where superior RF/analog circuitry based on nanotube devices can be combined with digital circuitry based on standard silicon CMOS.

In one or more embodiments, a method is provided that circumvents the need for depositing source/drain contacts to nanotube devices formed on a wafer or substrate in a front end CMOS process flow where the risk of contaminating CMOS circuitry formed on the wafer or CMOS fabrication equipment is high. In one or more embodiments, a method is provided that allows a modular path for integrating source/drain contacts to nanotube devices, regardless of where in the CMOS process flow the nanotube devices are integrated. In one or more embodiments, a method is provided that enables a self-aligned nanotube device to be formed on a wafer with source and drain contacts for the nanotube device being separated from the gate for the nanotube device by a spacer formed of a fixed width.

In one or more embodiments, the method of forming a nanotube field effect transistor semiconductor device includes forming a nanotube layer on a semiconductor substrate to be used in a CMOS process flow. A nanotube protection layer is deposited over the nanotube layer, wherein the nanotube protection layer also serves as a gate dielectric material. A plurality of gates are formed for a plurality of nanotube field effect transistors on the nanotube protection layer, where spacers are formed on opposing sides of each gate. A dielectric layer is deposed over the gates, spacers and exposed portions of the nanotube protection layer. Contact holes are then formed extending through the dielectric layer to the nanotube layer to expose portions of the nanotube layer. An ohmic contact material is deposited that extends into each of the contact holes and in contact with the exposed portions of the nanotube layer, where the ohmic contact material is further deposited over the surface of the dielectric layer. Metallic source/drain contacts are then formed in the contact holes in contact with the ohmic contact material.

### DRAWINGS

The above-mentioned features and objects of the present disclosure will become more apparent with reference to the following description taken in conjunction with the accompanying drawings wherein like reference numerals denote like elements and in which:

FIGS. 1-9 illustrate cross-sectional views of various stages of a CMOS compatible method of forming source/drain contacts to nanotube devices in accordance with one or more embodiments of the present disclosure.

### DETAILED DESCRIPTION

The present disclosure is directed to a CMOS compatible method of forming source/drain contacts to nanotube devices formed on the same wafer upon which CMOS processing is performed.

In one or more embodiments, a method is provided for forming source/drain contacts to nanotube devices formed on a wafer on which complementary metal oxide semiconductor (CMOS) circuitry can subsequently be formed in a standard CMOS process flow or upon which CMOS circuitry has already been formed using a standard CMOS process flow. The method forms source/drain contacts to the nanotube devices while minimizing the possibility of metal contamination to the CMOS circuitry formed on the wafer or CMOS fabrication equipment used in the CMOS process flow.

In one or more embodiments described herein, for ease of description, nanotube devices may be described as carbon nanotubes (CNTs), while it is understood that the nanotube devices may comprise any type of nanotubes, including but not limited to carbon nanotubes (CNTs), single walled nanotubes (SWNTS) and multiwalled nanotubes (MWNTs). Further, each of the various embodiments could also be implemented in any 1-D semiconductor device (e.g., nanotubes, nanowires, etc.) or 2-D semiconductor device (e.g., graphene-based devices, etc.).

In one or more embodiments, a method is provided that circumvents the need for depositing source/drain contacts (e.g., Pd or Ti/Au) to nanotube devices formed on a wafer in a front end CMOS process flow where the risk of contaminating CMOS circuitry formed on the wafer or CMOS fabrication equipment is high. Front end processes are those operations performed on a semiconductor wafer in the course of device manufacturing up to the first metallization, where back end processes are all operations performed on the semiconductor wafer in the course of device manufacturing following the first metallization. The present method avoids introducing Palladium (Pd) or other metallic ohmic contact materials that are not typically used in front end processes into the front end portion of a standard CMOS flow where the thermal budgets (maximum temperature×step time) are higher and the metallic content in the fabrication equipment is exceedingly low. To the contrary of front end processes, CMOS backend processes typically use Ti, Ta, Al, W, Co, or Cu metals for forming interconnects, contacts, and vias. Thus, in one or more embodiments, Pd or another metallic ohmic contact material is used in a CMOS backend process to form source/drain contacts to nanotube devices that are formed in a front end process, thereby reducing or eliminating the contamination risk to CMOS circuitry formed on the wafer or front end CMOS fabrication equipment. In one or more embodiments, a method is provided that enables a self-aligned nanotube device to be formed on a wafer with source and drain contacts for the nanotube device being separated from the gate for the nanotube device by a formed spacer of a fixed width.

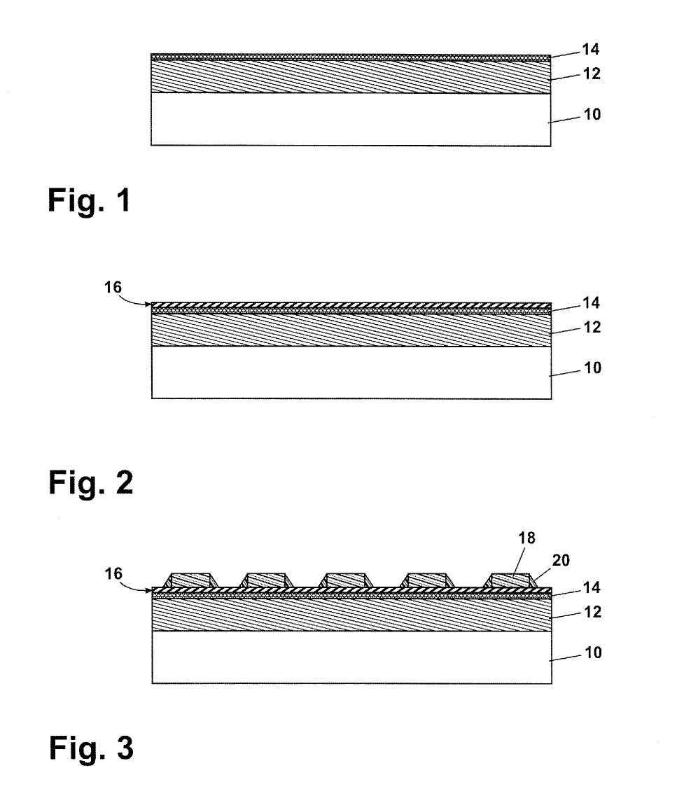

Referring now to FIGS. 1-9, cross-sectional views of various process steps in one or more embodiments of a CMOS compatible method of forming source/drain contacts to nanotube devices are illustrated. These process steps allow the seamless integration of nanotube devices in a CMOS process flow without the risk of contamination to CMOS circuitry formed on the wafer or front end CMOS fabrication equipment. As illustrated in FIG. 1, a layer of carbon nanotubes (CNTs) 14 are initially deposited on an oxide layer 12 that is formed on a substrate or wafer 10, where wafer 10 may be a p-type (P—Si) wafer or other type of wafer typically used in CMOS processes. The wafer 10 may further be a standalone wafer (as illustrated) or may be an integrated CMOS wafer.

As illustrated in FIG. 2, a nanotube protection layer 16 is then deposited over the CNTs 14, where in one or more embodiments the nanotube protection layer 16 layer serves a dual purpose of acting as a gate dielectric under gates for nanotube devices acting as FETs and further acts as a passivation layer elsewhere. Any suitable gate deposition method may be employed, including but not limited to atomic layer deposition (ALD) of the nanotube protection layer 16. Further, any suitable gate dielectric material may be utilized, including but not limited to Al₂O₃, HFO₂, ZrO₂, SiₓN_{y}, etc.

Referring now to FIG. 3, in one or more embodiments, gates 18 and spacers 20 for nanotube devices acting as FETs are formed. For instance, in one or more embodiments, gates 18 can be formed by depositing a gate electrode layer (e.g., polysilicon or any other conducting material known to those skilled in the art) that is then patterned with a photoresist material and etched to form the patterned gates 18 illustrated in FIG. 3. In one or more embodiments, the spacers 20 can be formed by depositing a layer of spacer material over the gates 18, where the spacer material may comprise silicon oxide, silicon nitride, or any other spacer material known to those skilled in the art that is used in semiconductor manufacturing processes. The layer of spacer material is then etched to form the spacers 20 on the side surfaces of gates 18. The spacers 20 are preferably formed to have a fixed width. It is understood that the gates 18 and spacers 20 can be formed using other gate/spacer formation techniques known to those skilled in the art of CMOS and nanotube processes.

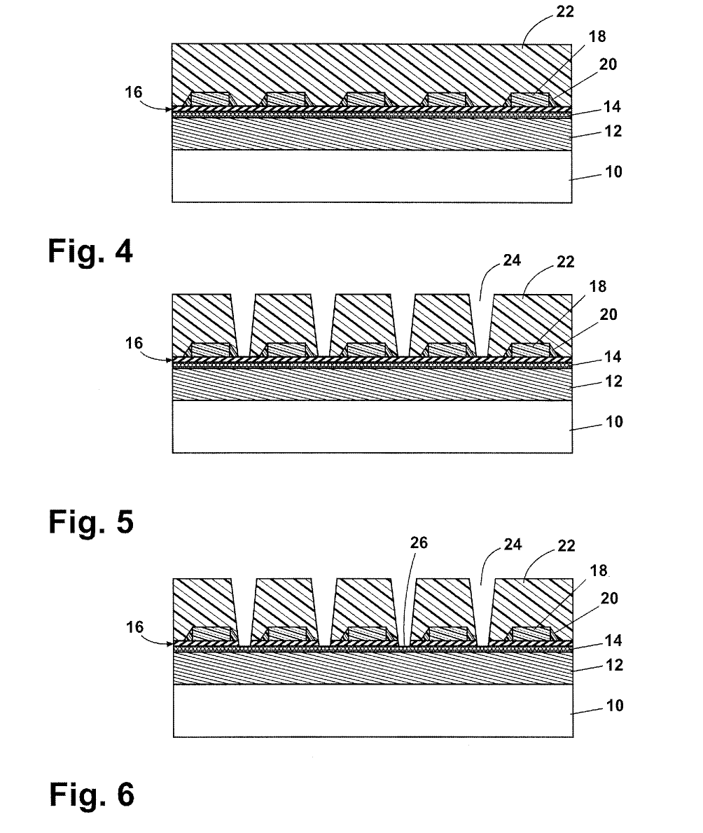

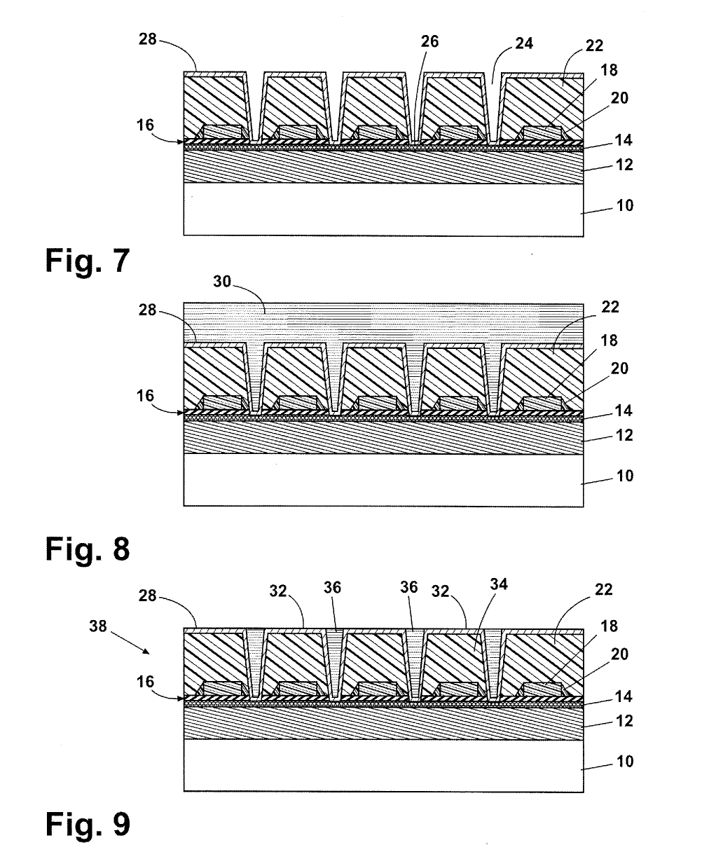

In one or more embodiments, a pre-metal dielectric (PMD) 22 is then deposited over the gates 18, spacers 20 and exposed portions of the nanotube protection layer 16 between the various gates 18 and spacers 20. The PMD 22 is planarized using a chemical mechanical polishing (CMP) step or other similar processing technique, as shown in FIG. 4. In one or more embodiments, PMD 22 may comprise silicon oxide, silicon oxynitride, or any suitable low-k dielectric material. Contact holes 24 are then etched in the pre-metal dielectric 22 down to and stopping at the nanotube protection layer 16, as shown in FIG. 5. The nanotube protection layer 16 at the base 26 of each contact hole 24 is then selectively removed from the contact holes 24 to expose portions of the CNTs 14 at the base 26 without harming or damaging the integrity of the CNTs 14, as illustrated in FIG. 6. In one or more embodiments, a layer of Palladium (Pd) 28 or another similar contact metal is then deposited on the surface of the structure so that it also extends within contact holes 24 to form ohmic contacts to the CNTs 14, as illustrated in FIG. 7.

Referring to FIG. 8, a layer of CMOS contact liner stack material 30 known to those skilled in the art (e.g., Ti, TiN, W, or other known liner stack material) is then deposited over the surface of the structure so as to also fill the contact holes 24. The upper surface of CMOS contact liner stack material 30 is then smoothed and planarized, such as by chemical mechanical polishing (CMP) (e.g., W-CMP) or other similar techniques, as illustrated in FIG. 9. In one or more embodiments, CMP is performed until the CMOS contact liner stack material 30 is removed from the surface 32 of the contact metal layer 28 on portions 34 of the structure extending between contact holes 24 while leaving the contact holes 24 filled with CMOS contact liner stack material 30 which then serves as metal contacts 36 for the sources and drains of the nanotube devices acting as FETs. Standard backend CMOS processes can then be performed or continued to be performed on the resulting device 38 illustrated in FIG. 9.

As can be seen from the foregoing, a method is provided for forming metal contacts for nanotube devices acting as FETs in a standard CMOS process flow using steps that allow the formation of metal contacts to nanotube devices with no risk of metal contamination to CMOS circuitry formed on the wafer with the nanotube devices or front end CMOS fabrication equipment. Further, the method is completely modular and is independent of how nanotube devices are integrated with CMOS devices.

Still further, the present method enables integrating carbon nanotube (CNT) devices and other nanotube devices with a standard CMOS process flow, thereby opening avenues to commercializing new generations of radio frequency (RF) CMOS technology where superior RF/analog circuitry based on nanotube devices can be combined with digital circuitry based on standard silicon CMOS. The present method further enables the formation of self-aligned nanotube devices by positioning contact holes touching the nanotube gate spacers where, the spacing between contact holes (and thereby contacts) is automatically determined by the width of the gate electrode and spacers formed on the sides of the gate electrode.

While the system and method have been described in terms of what are presently considered to be specific embodiments, the disclosure need not be limited to the disclosed embodiments. It is intended to cover various modifications and similar arrangements included within the spirit and scope of the claims, the scope of which should be accorded the broadest interpretation so as to encompass all such modifications and similar structures. The present disclosure includes any and all embodiments of the following claims.

1. A method of forming a nanotube field effect transistor semiconductor device, comprising:
forming a nanotube layer on a semiconductor substrate to be used in a CMOS process flow;
depositing a nanotube protection layer over the nanotube layer, wherein the nanotube protection layer also serves as a gate dielectric material;
forming at least one gate for a nanotube field effect transistor on the nanotube protection layer;
forming spacers on opposing sides of the at least one gate;
depositing a dielectric layer over the at least one gate, spacers and exposed portions of the nanotube protection layer;
forming contact holes extending through the dielectric layer to the nanotube layer to expose portions of the nanotube layer;
depositing an ohmic contact material that extends into each of the contact holes and in contact with the exposed portions of the nanotube layer, where the ohmic contact material is further deposited over the surface of the dielectric layer;
forming metallic contacts in the contact holes in contact with the ohmic contact material.

2. The method of claim 1, further comprising forming the metallic contacts by:
depositing a layer of metallic contact material over the ohmic contact material so that it fills the contact holes; and
polishing the metallic contact material to remove the metallic contact material from all areas except within the contact holes to form metallic contacts in the contact holes.

3. The method of claim 1, further comprising performing the method during back end processes of a CMOS process flow.

4. The method of claim 1, wherein the metallic contacts are formed as source and drain contacts for a nanotube field effect transistor.

5. The method of claim 1, further comprising planarizing the dielectric layer to form a smooth upper surface before forming the contact holes in the dielectric layer.

6. The method of claim 1, wherein the nanotube layer comprises a layer of carbon nanotubes.

7. The method of claim 1, further comprising forming a plurality of gates and contact holes, where the contact holes are equally spaced from one another by a fixed width determined by a combined width of the gate and the spacers formed on the sides of the gate.

8. The method of claim 1, wherein the contact holes are formed by:
etching a contact hole in the dielectric layer down to the nanotube protection layer; and
selectively removing the nanotube protection layer at a base of the contact hole to expose a portion of the nanotube layer at the base of the contact hole.

9. A method, comprising:
forming nanotube devices on a semiconductor substrate during a front end process of a CMOS process flow;
forming metallic contacts for the nanotube devices during a back end process of the CMOS process flow.

10. The method of claim 9, wherein the nanotube devices are nanotube field effect transistors and the metallic contacts are source and drain contacts for the nanotube field effect transistors.

11. The method of claim 9, wherein the metallic contacts are formed by:
forming a contact hole in a dielectric layer deposited on the semiconductor substrate to expose portions of the formed nanotube devices;
depositing an ohmic contact material that at least extends into each of the contact holes and in contact with the exposed portions of the nanotube devices;
depositing a metallic contact material over the ohmic contact material so that it fills the contact holes.

12. The method of claim 11, wherein the ohmic contact material is Palladium.

13. The method of claim 12, wherein the metallic contact material is at least one of Titanium, Titanium Nitride, Tungsten, Aluminum and Copper.

14. A method of forming a self-aligned nanotube field effect transistor (FET) device, comprising
forming a nanotube layer on a semiconductor substrate;
depositing a nanotube protection layer over the nanotube layer, wherein the nanotube protection layer also serves as a gate dielectric material;
forming at least one gate for a nanotube field effect transistor on the nanotube protection layer;
forming spacers on opposing sides of the at least one gate;
depositing a dielectric layer over the at least one gate, spacers and exposed portions of the nanotube protection layer;
forming contact holes through the dielectric layer extending adjacent to the spacers to the nanotube layer to expose portions of the nanotube layer;
depositing an ohmic contact material that extends into each of the contact holes and in contact with the exposed portions of the nanotube layer, where the ohmic contact material is further deposited over the surface of the dielectric layer;
forming metallic contacts in the contact holes in contact with the ohmic contact material, wherein the metallic contacts are self-aligned with one another due to the formation of each of the contact holes to be adjacent to the spacers such that the contact holes are equally spaced from one another by a fixed width determined by a combined width of the gate and the spacers formed on the sides of the gate.
